(19) United States
(12) Patent Application Publication
(10) Pub. No.: US 2012/0313095 A1
(43) Pub. Date: Dec. 13, 2012

(54) ELECTROSTATIC DISCHARGE PROTECTION CIRCUIT EMPLOYING POLYSILICON DIODE

(76) Inventor: Yen-Wei Liao, Miaoli County (TW)

(21) Appl. No.: 13/483,070

(22) Filed: May 30, 2012

(30) Foreign Application Priority Data
Jun. 10, 2011 (TW) 100120383

(51) Int. Cl. H01L 27/06

(52) U.S. Cl. 257/49; 257/E27.016; 257/E27.019

(57) ABSTRACT

An electrostatic discharge (ESD) protection circuit includes a polysilicon diode, a switch element, and a load element. The poly silicon diode has a first terminal and a second terminal. The switch element has a control terminal coupled to the first terminal of the polysilicon diode, a first terminal coupled to the second terminal of the polysilicon diode, and a second terminal. The load element is coupled to the control terminal of the switch element and the second terminal of the switch element.

### BACKGROUND OF THE INVENTION

1. Field of the Invention

The disclosed embodiments of the present invention relate to an electrostatic discharge protection circuit, and more particularly, to an electrostatic discharge protection circuit employing a polysilicon diode.

2. Description of the Prior Art

In general, an electrostatic discharge protection circuit is disposed in a semiconductor integrated circuit device to avoid large electrostatic discharge which may cause an internal circuit element malfunction or even damage/destroy the internal circuit element. The commonly used electrostatic discharge protection circuits rely on the breakdown voltage of the PN junction diode to determine whether to conduct a current for releasing charges resulting from the electrostatic discharge. However, a conventional electrostatic discharge protection circuit enables the electrostatic discharge protection mechanism according to a voltage drop generated by a breakdown current flowing through an N-well or a P-well. Therefore, the resistance of the N-well or P-well may be too small to successfully enable/activate the electrostatic discharge protection circuit, thus causing damage to the circuit. Furthermore, as the breakdown voltage of the PN junction diode is determined by the doping concentration thereof, the design flexibility is highly limited to manufacturing process, that is, designers may not select an arbitrary doping concentration of the PN junction diode to produce a desired breakdown voltage. Thus, when designers need various breakdown voltages, additional steps and masks have to be added to the manufacturing process, which increases the cost inevitably.

### SUMMARY OF THE INVENTION

In accordance with exemplary embodiments of the present invention, an electrostatic discharge protection circuit, which employs a polysilicon diode as a device for enabling the electrostatic discharge protection mechanism, is proposed to solve the abovementioned problems.

According to an embodiment of the present invention, an exemplary electrostatic discharge protection circuit is disclosed. The exemplary electrostatic discharge protection circuit includes a polysilicon diode, a switch element, and a load element. The polysilicon diode has a first terminal and a second terminal. The switch element has a control terminal coupled to the first terminal of the polysilicon diode, a first terminal coupled to the second terminal of the polysilicon diode, and a second terminal. The load element is coupled to the control terminal of the switch element and the second terminal of the switch element.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an exemplary electrostatic discharge protection circuit according to an embodiment of the present invention.

FIG. 2 is a diagram illustrating another exemplary electrostatic discharge protection circuit according to another embodiment of the present invention.

FIG. 3 is a diagram illustrating relation between the size of the polysilicon diode and the corresponding breakdown voltage.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is electrically connected to another device, that connection may be through a direct electrical connection, or through an indirect electrical connection via other devices and connections.

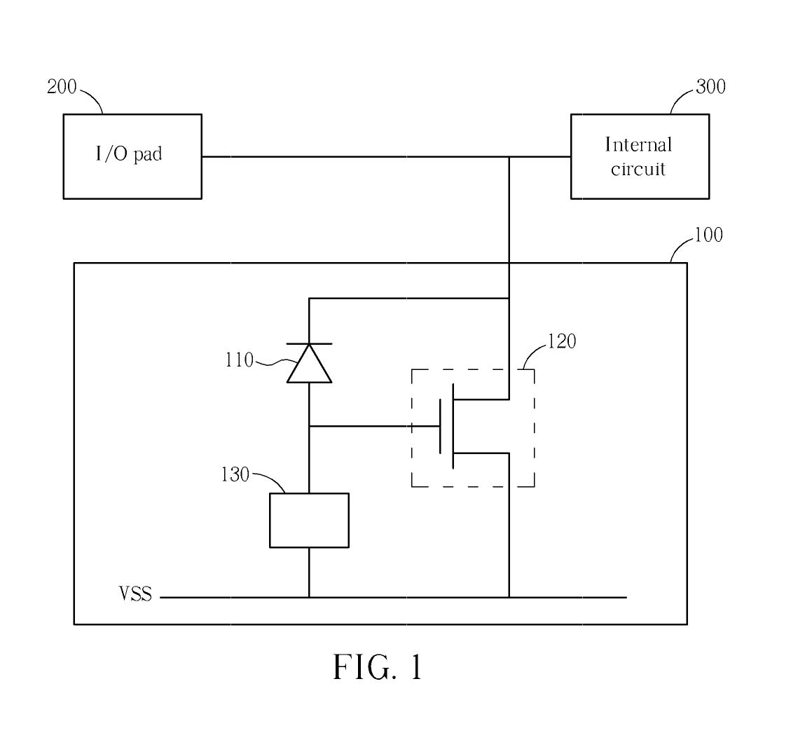

Please refer to FIG. 1, which is a diagram illustrating an exemplary electrostatic discharge protection (ESD) circuit according to an embodiment of the present invention. The exemplary ESD circuit 100 includes, but is not limited to, a polysilicon diode 110, a switch element 120, and a load element 130. The polysilicon diode 110 has a first terminal and a second terminal, and a protection voltage of the ESD protection circuit 100 (i.e., a threshold voltage required to enable the ESD mechanism) is proportional to a breakdown voltage of the polysilicon diode 110. A control terminal of the switch element 120 is coupled to the first terminal of the polysilicon diode 110, a first terminal of the switch element 120 is coupled to the second terminal of the polysilicon diode 110, and a second terminal of the switch element 120 is coupled to a reference voltage VSS. However, this is for illustrative purposes only, and is not meant to be a limitation of the present invention. For example, in an alternative design, the second terminal of the switch element 120 may be coupled to a ground voltage or a supply voltage. The load element 130 is coupled to the control terminal of the switch element 120 and the second terminal of the switch element 120, that is, the load element 130 is coupled to the reference voltage VSS. In addition, the second terminal of the polysilicon diode 110 and the first terminal of the switch element 120 are coupled to an input/output (I/O) pad 200 and an internal circuit 300. When the input/output pad 200 receives an error voltage larger than the protection voltage, the polysilicon diode 110 is enabled to charge the load element 130, which increases a voltage of the control terminal of the switch element 120 to turn on the switch element 120. Next, the received error voltage of the input/output pad 200 may be adjusted to the correct level by turning on the switch element 120, which prevents the internal circuit 300 from operating abnormally or being damaged due to the error voltage.

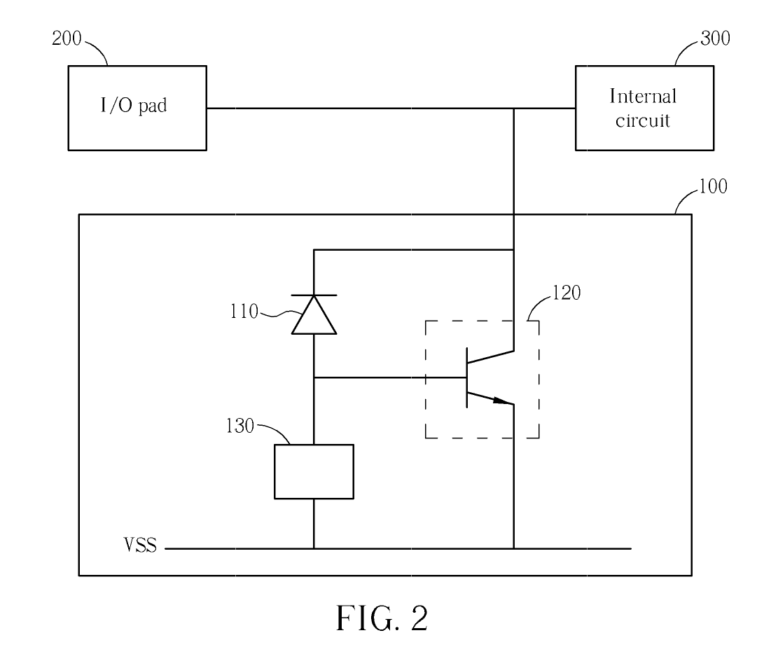

Please note that, in the embodiment shown in FIG. 1, the load element 130 is implemented by a resistor, and the switch element 120 is implemented by a metal-oxide-semiconductor (MOS) transistor. However, this is for illustrative purposes only, and is not meant to be a limitation of the present invention. For example, the switch element 120 may be a P-type or N-type MOS transistor, or a circuit element having a switch function. Please refer to FIG. 2, which is a diagram illustrating another exemplary ESD circuit according to another embodiment of the present invention. In this embodiment, the switch element 120 is implemented by an NPN or PNP bipolar junction transistor (BJT). These modifications and variations also fall within the scope of the present invention.

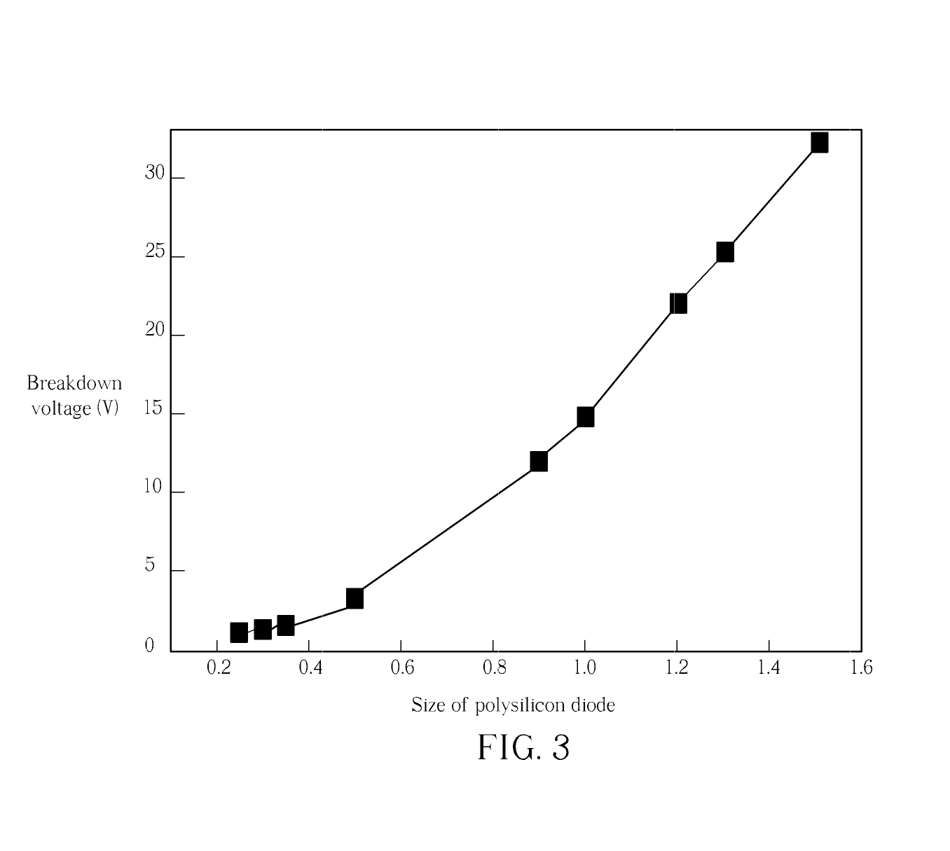

The proposed ESD circuit employs polysilicon to implement a diode therein. Therefore, no matter which manufacturing process is employed, due to the inherent characteristics of the polysilicon diode, the proposed ESD circuit may easily achieve the objective of adjusting the breakdown voltage by changing the size of the polysilicon diode. Please refer to FIG. 3, which is a diagram illustrating relation between the size of the polysilicon diode and the corresponding breakdown voltage. As shown in FIG. 3, the breakdown voltage is proportional to the size of the polysilicon diode substantially. Thus, designers may design polysilicon diodes based on different requirements. For example, when intending to design protection voltages of 5V, 10V, and 15V on the same input/output pad, a designer may achieve the design goal merely by selecting appropriate polysilicon diode sizes with reference to the relation between the size of the polysilicon diode and the breakdown voltage as shown in FIG. 3, and then disposing the polysilicon diodes having the selected sizes onto the circuit layout. In contrast to the conventional ESD circuit using the PN junction diode, the proposed ESD circuit may achieve the objective of realizing various protection voltages without additional masks in the manufacturing process, which greatly improves the design efficiency and cost reduction.

To sum up, an ESD circuit, which employs a polysilicon diode as a device for enabling the electrostatic discharge protection mechanism, is proposed. Due to the inherent characteristics of the polysilicon diode, the proposed ESD circuit may easily achieve the objective of adjusting the breakdown voltage by changing the size of the polysilicon diode. Therefore, the design flow and cost reduction are improved greatly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electrostatic discharge (ESD) protection circuit, comprising:
a polysilicon diode, having a first terminal and a second terminal;
a switch element, having a control terminal coupled to the first terminal of the polysilicon diode, a first terminal coupled to the second terminal of the polysilicon diode, and a second terminal; and
a load element, coupled to the control terminal of the switch element and the second terminal of the switch element.

2. The ESD protection circuit of claim 1, wherein the switch element is a metal-oxide-semiconductor (MOS) transistor.

3. The ESD protection circuit of claim 1, wherein the switch element is a bipolar junction transistor (BJT).

4. The ESD protection circuit of claim 1, wherein the load element is a resistor.

5. The ESD protection circuit of claim 1, wherein the second terminal of the polysilicon diode and the first terminal of the switch element are coupled to an input/output pad.

6. The ESD protection circuit of claim 1, wherein the second terminal of the switch element is coupled to a reference voltage.

7. The ESD protection circuit of claim 1, wherein a protection voltage of the ESD protection circuit is proportional to a breakdown voltage of the polysilicon diode.
